(19) United States
(12) Patent Application Publication
(10) Pub. No.: US 2012/0298866 A1
(43) Pub. Date: Nov. 29, 2012

(54) SNOWMOBILE AND METHOD FOR DRIVING A SNOWMOBILE

(76) Inventor: Julian Stevens, London (GB)

(21) Appl. No.: 13/576,730

(22) PCT Filed: Sep. 2, 2011
(86) PCT No.: PCT/GB2011/001294

§ 371 Date: Aug. 2, 2012

(30) Foreign Application Priority Data
Sep. 2, 2010 (GB) 1014599.3

(51) Int. Cl. H01L 31/12; F21V 21/088; F21V 5/04; B01J 19/12

(52) U.S. Cl. 250/330; 250/493.1; 250/504 R; 362/549; 362/520

(57) ABSTRACT

A snowmobile is disclosed, the snowmobile comprising a terrain visualization device. The device comprises a mounting structure fixed to the snowmobile, and a light emitting unit attached to the mounting structure. The light emitting unit is configured to project a predetermined contrast pattern onto terrain in front of the snowmobile in use. A method for driving a snowmobile across terrain is also disclosed, the method comprising projecting a predetermined contrast pattern onto the terrain using a light emitting unit while driving the snowmobile across the terrain, so that the topography of the terrain can be determined from distortion of the contrast pattern.

### RELATED APPLICATIONS

The present application is a National Phase entry of PCT Application No. PCT/GB2011/001294, filed Sep. 2, 2011, which claims priority from Great Britain Application Number 1014599.3, filed Sep. 2, 2010, the disclosures of which are hereby incorporated by reference herein in their entirety.

### FIELD OF INVENTION

The present invention relates to a snowmobile comprising a terrain visualization device that projects a pattern of light onto the terrain, allowing a user to see the topography of the terrain even in poor lighting conditions. The invention also relates to a method for driving a snowmobile.

### BACKGROUND

There is a common problem encountered in skiing when lighting conditions are poor, whether due to low cloud or the time of day. In such conditions, sunlight may not produce shadows on the snow, either due to the sun being obscured by cloud or due to the position of the sun in the sky. It is very difficult for a skier to see the topography of the terrain without shadows on the snow because the snow-covered ground appears as a uniform white sheet, without color or luminance contrast.

The above problem is particularly dangerous in winter sports such as skiing, snowboarding and mono-skiing, where it can lead to accidents caused by the skier unexpectedly either leaving the ground or hitting a bump in the snow. However, the same problem is encountered when traversing snow-covered ground by any means including walking and driving a vehicle.

A similar problem is also encountered when traversing other types of terrain that are uniform in appearance and do not provide sufficient color or luminance contrast to see their topography in poor light. For example, the problem can also be encountered in water sports such as waterskiing in low light, or when hiking at night.

### SUMMARY OF THE INVENTION

Embodiments are designed to overcome the above problems by allowing a user to see the topography of terrain despite poor lighting conditions. Embodiments are designed to achieve this using much less energy than would be required to fully illuminate the terrain.

According to an embodiment, there is provided a snowmobile comprising a terrain visualization device, the device comprising: a mounting structure fixed to a snowmobile; and a light emitting unit attached to the mounting structure and configured to project a predetermined contrast pattern onto terrain in front of the snowmobile in use.

The pattern projected by the light-emitting device is distorted by the terrain as seen by the user. Since the user is familiar with the undistorted shape of the pattern, as projected onto flat ground, the user can easily deduce the shape of the terrain from the distorted pattern and can react accordingly. There is no need for the user to actually be able to see features of the terrain, its shape is inferred by the distortion of the pattern. Hence, embodiments operate completely differently from a conventional illumination device. A conventional illumination device would require sufficient power to illuminate the entire area of terrain ahead of the user, whereas embodiments only project onto a fraction of that area and relies on contrast between the projected pattern and the surrounding terrain rather than illumination of the terrain itself.

In other words, an illumination device such as a headlight must illuminate the terrain with sufficient power that a visible luminance contrast is created by differences in reflectivity of the terrain as seen by the user. On the other hand, embodiments create its own luminance contrast by projecting a pattern, which requires much less power.

In embodiments, the light emitting unit includes a laser light source. Suitably, the laser light source is a class 1 laser. In an embodiment, the laser light source has a power output of 5 mW or less.

Alternatively, the light emitting unit includes a superluminescent diode light source.

In embodiments, the mounting structure includes a light source holder and the light emitting unit is detachably attached to the light source holder.

In embodiments, the predetermined contrast pattern comprises at least one of a line and a dot. In one embodiment, the predetermined contrast pattern is a two-dimensional pattern of lines and/or dots.

Using a pattern of lines and/or dots reduces the surface area of the projected pattern and hence the power consumption of the device, while providing a clearly visible contrast pattern. Using a two-dimensional pattern allows the user to see the shape of the terrain in three dimensions without difficulty.

Suitably, the predetermined contrast pattern comprises a plurality of dots.

In embodiments, the predetermined contrast pattern comprises a straight line. Conveniently, the predetermined contrast pattern comprises at least one of an arc, a regular polygon, a circle, a cross, a grid and a regular dot array. In one embodiment, the number of lines in the predetermined contrast pattern is between 1 and 4.

Using a straight line or a regular shape for the projected pattern allows distortion in the pattern to be seen more easily. Straight lines are advantageous in embodiments because it is easier to manufacture a light source capable of projecting a straight line than one capable of projecting more complex shapes. In particular, using between 1 and 4 lines in the pattern provides a good balance between ease of manufacture and accurate visualization of the terrain.

In embodiments, the light emitting unit comprises at least one of a lens and a holographic plate for generating the predetermined contrast pattern.

In embodiments, the light emitting unit is adapted to project the predetermined contrast pattern continuously.

Alternatively, the light emitting unit is adapted to project the predetermined contrast pattern intermittently. Suitably, the light emitting unit is adapted to project the predetermined contrast pattern repeatedly at a preset frequency. In one embodiment, the light emitting unit is adapted to project the predetermined contrast pattern for a preset duration.

Conveniently, the light emitting unit is adapted to project the predetermined contrast pattern in response to operation of a switch.

In embodiments, the light emitting unit is adapted to emit narrowband light. More preferably, the light emitting unit is adapted to emit light in the visible spectrum.

In one embodiment, the light emitting unit is adapted to emit light outside the visible spectrum. Suitably, the light emitting unit is adapted to emit infra-red light.

In one embodiment, there is provided a system comprising the snowmobile comprising a terrain visualization device adapted to emit light outside the visible spectrum described above and an optical sensing apparatus, wherein the optical sensing apparatus is adapted to detect the light outside the visible spectrum emitted by the light emitting unit and reflected from the terrain and to display the light outside the visible spectrum as visible light, to allow the user to see the predetermined contrast pattern projected onto the terrain.

According to another embodiment, there is provided a method for driving a snowmobile across terrain, comprising projecting a predetermined contrast pattern onto the terrain using a light emitting unit while driving the snowmobile across the terrain, so that the topography of the terrain can be determined from distortion of the contrast pattern.

### BRIEF DESCRIPTION OF THE DRAWINGS

Embodiments of the present invention will now be described by way of further example only and with reference to the accompanying drawings, in which:

FIG. 1 shows a skier using a device according to an embodiment of the invention;

FIG. 2 is a schematic diagram of a belt-mounted visualization device according to an embodiment of the invention;

FIG. 3 is a schematic diagram of a head-mounted visualization device according to an embodiment of the invention;

FIG. 4 is a schematic diagram of a visualization device according to an embodiment of the invention designed to be clipped to a belt or strap;

FIGS. 5(A) to 5(F) illustrate patterns of light emitted by devices according to embodiments of the invention; and

FIG. 6 illustrates the distortion of a cross-shaped light pattern according to an embodiment of the invention by uneven terrain.

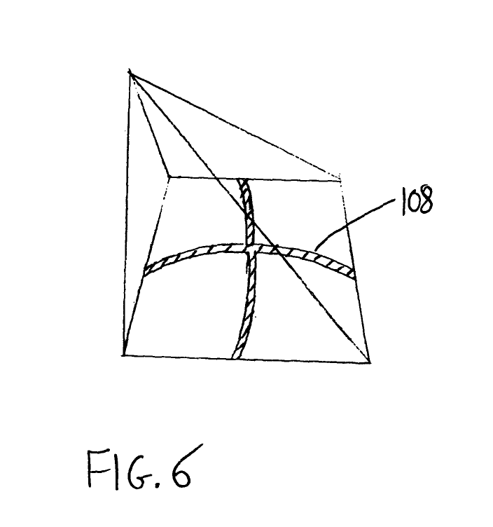

### DESCRIPTION OF THE PREFERRED EMBODIMENTS

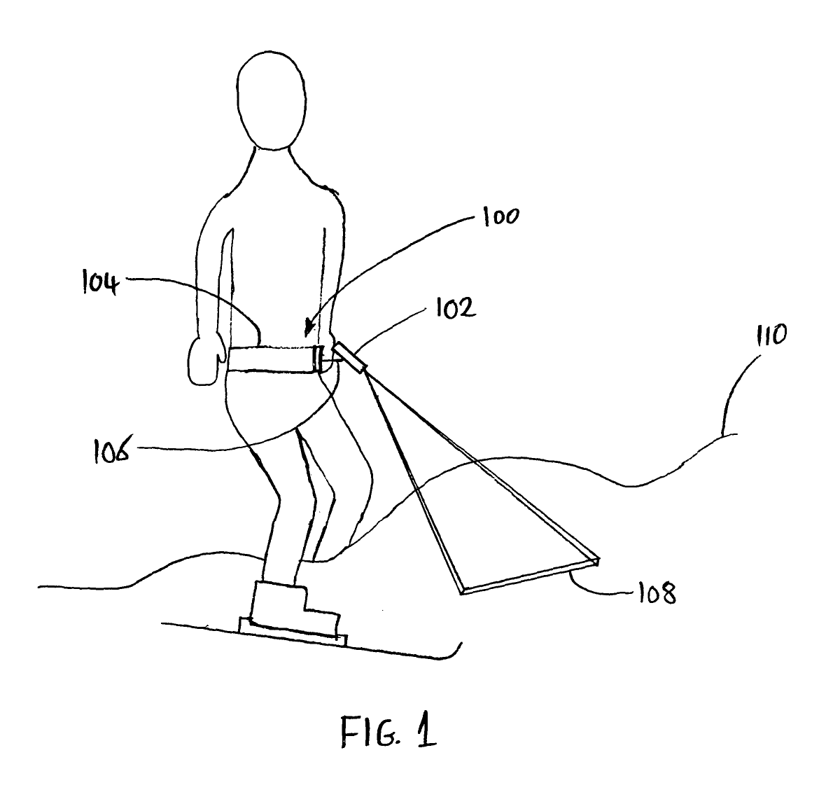

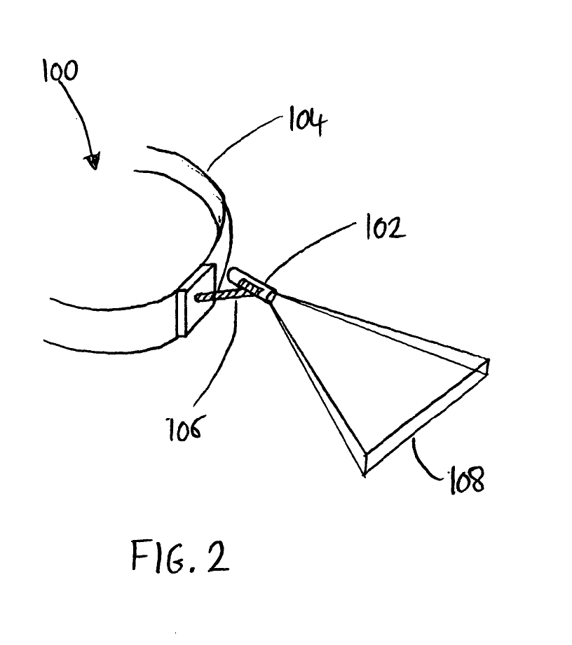

As shown in FIGS. 1 and 2, a device 100 according to an embodiment includes a light emitting unit 102 attached to a mounting structure 104. The mounting structure 104 includes a belt and a light source holder 106. The device 100 projects a predetermined contrast pattern of light 108 onto terrain 110 in front of a user.

In this embodiment, the light emitting unit 102 comprises a laser diode and complies with the ANSI Z136 and IEC 60825 standards. However, any light source sufficiently bright and directional to project a contrast pattern onto a terrain surface from a distance of a few meters can be used. In particular, a coherent light source is not required and a non-coherent source such as a superluminescent diode (SLED) can be used instead.

The power of the light source must be sufficient in embodiments for the user to see the contrast pattern projected by the light source onto the ground. However, the light source must not be so powerful in embodiments that it could cause eye injury to the user or other people nearby. Class I lasers, which are eye safe, and SLEDs are particularly suitable as the light source in embodiments for this reason. A Class II/2 laser with a power of up to 1 mW is also relatively eye safe and is suitable for use as the light source. A Class IIIa/3R laser with a power of up to 5 mW can be used as the light source but must be operated with due caution.

The wavelength of the light source is not particularly limited. Of course, any color of visible light can be used but it is also possible to use wavelengths outside the visible spectrum if the device 100 is designed to be used in conjunction with an optical sensing apparatus detecting the wavelength used. For example, it is possible to use an infra-red light source so that the projected pattern can be seen using thermal night vision goggles. A Nd:YAG infra-red laser is particularly suited to be the light source in this embodiment. Using a light source emitting light outside the visible spectrum has the advantage that the projected pattern is only visible to a user with appropriate equipment, such as thermal goggles. This means that the contrast pattern will not distract others nearby, for example other skiers on a ski slope. This embodiment is particularly useful at night, when infra-red night vision goggles would be used in any case.

The light emitting unit 102 is configured to project a contrast pattern 108 onto the terrain surface. The pattern 108 can be a single line, it is only necessary for the user to be able to detect the topography of the terrain onto which the pattern 108 is projected based on the distortion of the pattern 108. The device 100 is effective because the user knows the shape of the projected pattern 108 on a flat surface and can thus infer the topography of the terrain by comparing the distorted pattern 108 with the known flat surface pattern 108. This process quickly becomes intuitive and then does not require conscious thought on the part of the user.

In this embodiment, the laser diode projects a single straight line pattern 108. This can be achieved by using a laser diode that has a line-shaped (i.e. relatively long compared to its width) light-emitting area, or by passing light from the diode through a lens or slit in the desired shape. Alternatively a holographic plate can be used to generate the light pattern projection. Suitable methods for generating a line pattern are described in U.S. Pat. Nos. 4,321,551 and 6,069,748 which are hereby incorporated by reference in their entireties.

The light emitting unit 102 is attached to a belt in this embodiment, so that the device 100 can be attached to the waist of a user. The belt has a light source holder 106 fixed to it and the light emitting unit 102 is detachably clipped into the light source holder 106. However, the light emitting unit 102 can also be integral to the mounting structure 104. In an embodiment, the light emitting unit 102 can be detachable so that it can be replaced in the event of failure.

The light source holder 106 forms part of the buckle on the front of the belt in this embodiment. However, the light source holder 106 can also be fixed to the material of the belt itself, either at the front or to one side. The light source holder 106 holds the light emitting unit 102 in such a way that its position and angle are fixed in use. The light source holder 106 holds the light emitting unit 102 at a position and angle such that when the belt is worn by a user, the light emitting unit 102 projects the pattern 108 onto the terrain in front of the user.

In this embodiment, the light emitting unit 102 is held at an angle such that the pattern 108 is projected onto the terrain approximately 2 to 4 m in front of the user when the belt is attached to the user's waist. The distance in front of the user should be sufficiently short that the pattern 108 is clearly visible but sufficiently far that the user has time to react to changes in the terrain. The optimal distance varies depending upon the expected lighting conditions and speed of the user among other factors, but a distance of between 2 m and 6 m has been found to be suitable for most applications.

In the above embodiment, the device 100 is mounted to the waist of a user. This arrangement is advantageous because the user's waist does not tend to move independently as much as other body parts, which makes the pattern 108 projected by the device 100 more stable on the terrain and hence easier to read. However, the device 100 can also be configured to be attached to any other body part of the user.

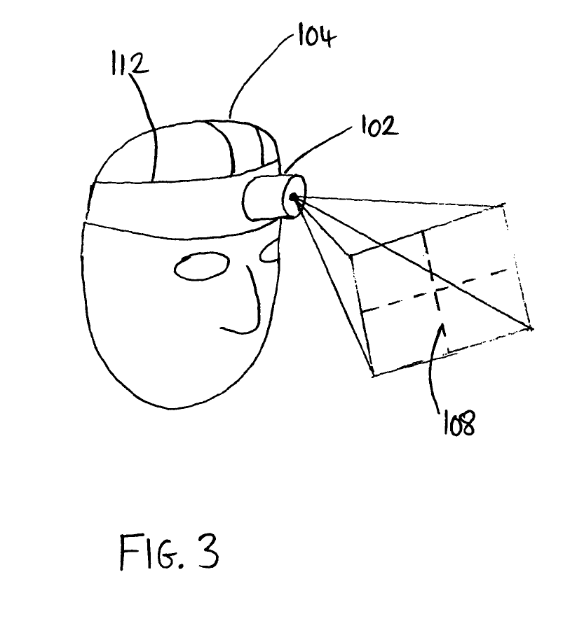

A head-mounted device 100 according to another embodiment is shown in FIG. 3. The device 100 includes a head strap 112, which can be attached directly to the head of the user or can be attached to a helmet. A light emitting unit 102 as described above is fixed to a front portion of the head strap 112. The light emitting unit 102 is configured so that when the head strap 112 is worn by the user, the pattern 108 projected by the light emitting unit 102 is projected onto the ground with the user's head at a comfortable angle. The head-mounted device 100 has the advantage that the user can select a piece of terrain on which to project the pattern 108 simply by a head movement. This is particularly useful when the user needs to change direction suddenly.

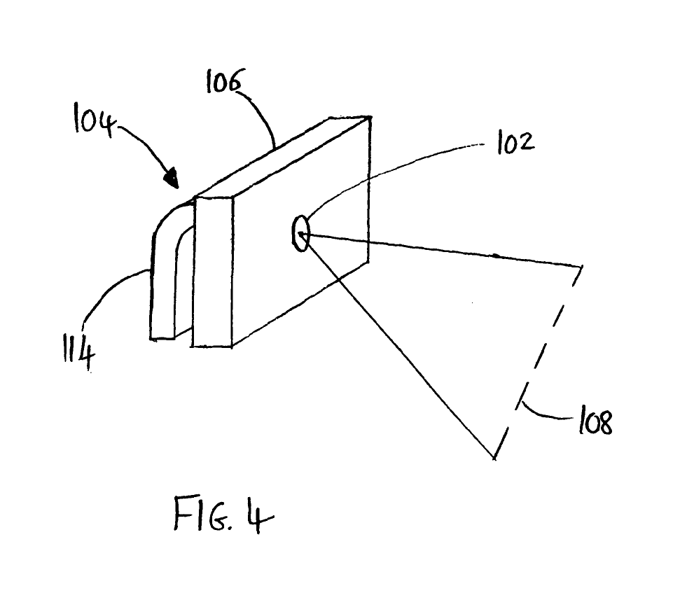

In the above embodiments, the mounting structure 104 includes the belt or head strap 112. However, it is also possible to provide a mounting structure 104 consisting only of a light source holder 106 having a belt clip 114 as well as a portion configured to engage with and hold the light emitting unit 102, as shown in FIG. 4. In the embodiment shown in FIG. 4, the light emitting unit 102 is fitted into a hole in the light source holder 106. The mounting structure 104 can then be clipped onto an existing belt or other item of clothing so as to fix the light emitting unit 102 to the user's waist or other body part. The precise form of the mounting structure 104 is not important to the invention provided that it is capable of securely attaching the light emitting unit 102 to the user's body.

This embodiment has the advantage that it can be interchangeably attached to a belt as shown in FIG. 2, to a head strap as shown in FIG. 3 and to a range of other wearable accessories.

The terrain visualization device 100 can also be clipped or otherwise attached to the front of a vehicle, such as a mountain bike or snowmobile, so as to project the pattern 108 onto the ground and provide terrain visualization when driving the vehicle.

In an alternative embodiment, the device 100 can be attached to a static object such as a ski lift pylon or a tree. The device 100 is mounted to the static object in such a way that the light source projects the pattern 108 onto a nearby area of terrain, enabling any passer by to see the topography of that piece of terrain. In this embodiment, the mounting structure 104 is adapted to fix the light emitting unit 102 securely to the desired static object so as to point downwards, towards the area of terrain to be illuminated. For example, the mounting structure 104 in one embodiment is an adjustable strap and buckle adapted to be wrapped around the trunk of a tree. The light source holder 106 is fixed to the buckle at a downwards-facing angle and friction between the strap and the tree trunk holds the device 100 in position. This embodiment is particularly useful in a ski resort, where specific areas of a ski run may be known to be dangerous. A device 100 according to an embodiment can be mounted to a static object at the side of the ski run so as to project a pattern 108 onto a dangerous area, for example a steep-sided bump. In this way, any skier coming down the run will be able to see the bump and react appropriately, even in poor light.

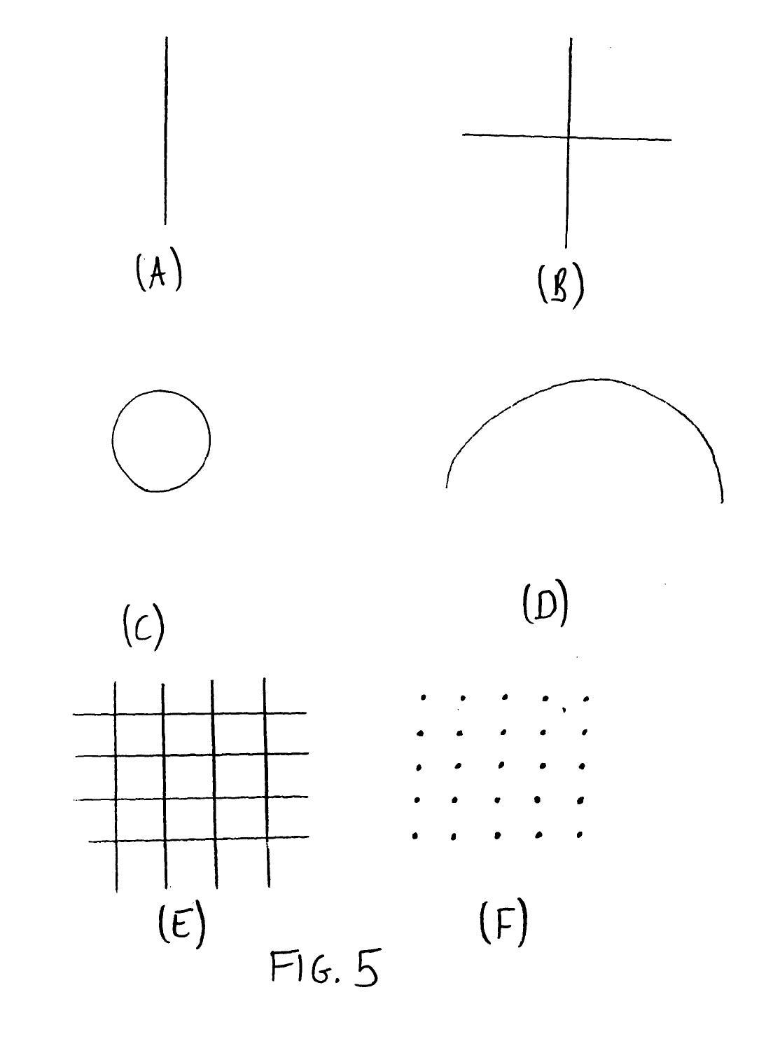

The light emitting unit 102 can be configured to project a wide range of different patterns 108. A single line has the advantage of simplicity and ease of manufacture. However, a two-dimensional pattern 108 provides greater information on the shape of the terrain in three dimensions. A pattern 108 made up of regular shapes is advantageous in embodiments because it makes the distortion caused by the underlying terrain more apparent and easier for the user to interpret. However, irregular shapes can also be used. Examples of suitable projection contrast patterns 108 are illustrated in FIG. 5. These shapes are a straight line, a cross, a circle, an arc, a grid and a regular array of dots respectively.

In one modification, the pattern 108 is an array of parallel lines. In an embodiment, this pattern includes between 2 and 4 parallel lines.

In embodiments, the contrast pattern 108 can be made up of lines and/or dots rather than large blocks of light because this greatly reduces the power consumption of the light emitting unit 102. As discussed above, a major advantage of embodiments is that the shape of the terrain is inferred indirectly through distortion of the projected contrast pattern 108. As a result, there is no need to illuminate a large area of terrain so that the features of the terrain are directly visible.

The light emitting unit 102 projects the pattern 108 continuously when the device 100 is switched on in this embodiment. However, the light emitting unit 102 can alternatively be configured to project the pattern 108 intermittently. The light emitting unit 102 can project the pattern 108 at a preset frequency for a present duration, for example at 2 Hz for 100 ms at a time.

The light emitting unit 102 can also be configured to project the pattern 108 only at certain times of day, for example between sunset and dawn. In this case, the device 100 is further provided with a timer and/or light sensor and circuitry for turning the light source on and off in response to the output of the timer and/or light sensor. Alternatively, the light emitting unit 102 can only be activated in embodiments when a low contrast condition is detected. In this case, the device 100 is further provided with a contrast sensor and circuitry for turning the light source on and off in response to the output of the contrast sensor.

A switch can provided on the device 100 and the light emitting unit 102 can be configured to project the pattern 108 only when the switch is activated by the user. In this way, the power consumption of the device 100 is further decreased because the time for which the light emitting unit 102 is active is reduced.

The light emitting unit 102 can be powered by an electrical power source such as a battery, as is conventional.

The foregoing description has been given by way of example only and it will be appreciated by a person skilled in the art that modifications can be made without departing from the scope of the present invention.

1. A terrain visualisation device for a snowmobile, the device comprising:
a mounting structure adapted to be fixed to a snowmobile; and
a light emitting unit attached to the mounting structure and configured to project a predetermined contrast pattern onto terrain when the mounting structure is fixed to the snowmobile.

2. A device according to claim 1, wherein the light emitting unit includes a laser light source.

3. A device according to claim 2, wherein the laser light source is a class 1 laser.

4. A device according to claim 2 or claim 3, wherein the laser light source has a power output of 5 mW or less.

5. A device according to claim 1, wherein the light emitting unit includes a superluminescent diode light source.

6. A device according to any one of claims 1 to 5, wherein the mounting structure is adapted to be attached to the snowmobile so that the light emitting unit projects the predetermined contrast pattern onto terrain in front of the snowmobile in use.

7. A device according to claim 6, wherein the mounting structure is adapted to be clipped detachably to the front of the snowmobile.

8. A device according to any one of claims 1 to 7, wherein the mounting structure is adapted to be attached to a handlebar of the snowmobile.

9. A device according to any one of claims 1 to 8, wherein the mounting structure includes a light source holder and the light emitting unit is detachably attached to the light source holder.

10. A device according to any one of claims 1 to 9, wherein the predetermined contrast pattern comprises at least one of a line and a dot.

11. A device according to claim 10, wherein the predetermined contrast pattern is a two-dimensional pattern of lines and/or dots.

12. A device according to claim 10, wherein the predetermined contrast pattern comprises a plurality of dots.

13. A device according to claim 10, wherein the predetermined contrast pattern comprises a straight line.

14. A device according to claim 10, wherein the predetermined contrast pattern comprises at least one of an arc, a regular polygon, a circle, a cross, a grid and a regular dot array.

15. A device according to claim 10, wherein the number of lines in the predetermined contrast pattern is between 1 and 4.

16. A device according to any one of claims 1 to 15, wherein the light emitting unit comprises at least one of a lens and a holographic plate for generating the predetermined contrast pattern.

17. A device according to any one of claims 1 to 16, wherein the light emitting unit is adapted to project the predetermined contrast pattern continuously.

18. A device according to any one of claims 1 to 16, wherein the light emitting unit is adapted to project the predetermined contrast pattern intermittently.

19. A device according to claim 18, wherein the light emitting unit is adapted to project the predetermined contrast pattern repeatedly at a preset frequency.

20. A device according to claim 18 or claim 19, wherein the light emitting unit is adapted to project the predetermined contrast pattern for a preset duration.

21. A device according to any one of claims 1 to 20, wherein the light emitting unit is adapted to project the predetermined contrast pattern in response to operation of a switch.

22. A device according to any one of claims 1 to 21, wherein the light emitting unit is adapted to emit narrowband light.

23. A device according to any one of claims 1 to 22, wherein the light emitting unit is adapted to emit light in the visible spectrum.

24. A device according to any one of claims 1 to 22, wherein the light emitting unit is adapted to emit light outside the visible spectrum.

25. A device according to claim 24, wherein the light emitting unit is adapted to emit infra-red light.

26. A system comprising the device according to claim 24 or claim 25 and an optical sensing apparatus,
wherein the optical sensing apparatus is adapted to detect the light outside the visible spectrum emitted by the light emitting unit and reflected from the terrain and to display the light outside the visible spectrum as visible light, to allow the user to see the predetermined contrast pattern projected onto the terrain.

27. A snowmobile comprising the terrain visualisation device according to any one of claims 1 to 25.

28. A snowmobile according to claim 27, wherein the terrain visualisation device is attached to the front of the snowmobile so as to project the predetermined contrast pattern onto the ground and provide terrain visualisation when driving the snowmobile.

29. A snowmobile according to claim 28, wherein the terrain visualisation device is detachably clipped to the front of the snowmobile.

30. A snowmobile according to any of claims 27 to 29, wherein the terrain visualisation device is attached to a handlebar of the snowmobile.

31. A method for driving a snowmobile across terrain, comprising projecting a predetermined contrast pattern onto the terrain using a light emitting unit, so that the topography of the terrain can be determined from distortion of the contrast pattern.

32. A method according to claim 31, wherein the predetermined contrast pattern comprises at least one of a line and a dot.

33. A method according to claim 32, wherein the predetermined contrast pattern is a two-dimensional pattern of lines and/or dots.

34. A method according to claim 32 or claim 33, wherein the number of lines in the predetermined contrast pattern is between 1 and 4.

35. A method according to any one of claims 31 to 34, wherein the light emitting unit comprises at least one of a lens and a holographic plate for generating the predetermined contrast pattern.

36. A method according to any one of claims 31 to 35, wherein the light emitting unit is attached to the front of the snowmobile.
